(19) United States
(12) Patent Application Publication
(10) Pub. No.: US 2010/0253607 A1
(43) Pub. Date: Oct. 7, 2010

(54) ORGANIC ELECTROLUMINESCENCE DISPLAY APPARATUS

(75) Inventor: Atsushi Shiozaki, Kawasaki-shi (JP)

Correspondence Address: FITZPATRICK CELLA HARPER & SCINTO, 1290 Avenue of the Americas, NEW YORK, NY, 10104-3800, US

(73) Assignee: CANON KABUSHIKI KAISHA, Tokyo (JP)

(21) Appl. No.: 12/670,930

(22) PCT Filed: Aug. 27, 2008
(86) PCT No.: PCT/JP2008/065787

§ 371 Date: Jan. 27, 2010

(30) Foreign Application Priority Data
Aug. 30, 2007 (JP) 2007-223649

(51) Int. Cl. G09G 3/30

(52) U.S. Cl. 345/76

(57) ABSTRACT

Provided is an organic electroluminescence display apparatus including: a substrate; a polarizing plate disposed on a display surface side being an opposite side of the substrate; a thin film transistor; and a planarization layer for reducing an irregular form corresponding to a circuit pattern of the thin film transistor, the planarization layer including a pixel electrode and an organic electroluminescence device and including at least two layers, a thickness of each of the planarization layers being set to be smaller than a maximum height of irregularities resulting from the thin film transistor, each of the planarization layers including a contact hole provided at a distinct planar position and a connection wiring layer capable of electrically connecting the thin film transistor and the pixel electrode via the contact hole, and a tapered portion of the planarization layer closest to the organic electroluminescence device having 30 degrees or less.

### TECHNICAL FIELD

The present invention relates to an organic electroluminescence (hereinafter, abbreviated as EL) display apparatus. In particular, the present invention relates to an organic EL display apparatus of an active matrix system, including a polarizing plate which is disposed on a display surface side being an opposite side of a substrate, and a planarization layer for reducing irregularities resulting from a circuit pattern of a thin film transistor.

### BACKGROUND ART

Currently, an organic EL display apparatus whose development has generally advanced has, as a basic structure, an organic EL device including a first electrode layer formed on a substrate, an organic compound layer including multiple layers having individual functions relating to charge transport and recombination, and a second electrode layer, the organic compound layer and the second electrode layer being stacked on the first electrode layer.

In the development relating to a drive system for full-color flat display, its priority is moving from a passive matrix system to an active matrix system in which a thin film transistor is provided to each pixel.

In an organic EL display apparatus of the active matrix system, a top-emission type in which an upper portion of a thin film transistor is also used as a pixel and light is taken out from a side opposite to a substrate has attracted more attention than a bottom-emission type in which light is taken out in a substrate direction. In the organic EL display apparatus having the top-emission structure, a planarization layer made of an organic resin is generally used to reduce irregularities resulting from the thin film transistor. In addition, the planarization layer is provided with a contact hole having a tapered side wall, through which the thin film transistor in a lower portion and the first electrode layer in an upper portion of the organic EL device are electrically connected.

Moreover, in a display apparatus, it is important to display with an appropriate contrast. Accordingly, a technology has been developed, in which a polarizing plate is used and a reflective layer is formed to enhance contrast, thereby preventing light entering from the outside from radiating to the outside again by the use of a phase change due to reflection (see Japanese Patent Application Laid-Open No. 2001-93665).

Meanwhile, it is known that when light entering from the outside is scattered by the side wall of the contact hole, reflection other than a suitable phase change occurs, and therefore an anti-reflection effect is lowered in the polarizing plate.

In other words, in order to reduce irregularities resulting from the thin film transistor, the thickness of the planarization layer is necessary to be set to about a height of the irregularities or larger. In order to obtain electrical connection at the same time, the contact hole is needed to be provided to the planarization layer. In this case, the side wall of the contact hole has to be tapered to obtain satisfactory electrical connection, but the tapered shape causes light to be scattered in various directions. For that reason, a part of the reflected light includes light having a phase which is not blocked by the polarizing plate, and the anti-reflection effects by the polarizing plate cannot be exerted sufficiently. In other words, the polarizing plate is provided to use an effect of confining the reflected light on a flat surface. Besides, rotation of a phase angle due to reflection is used. In this case, when light having an oblique component is generated, various reflections are generated, and thus a part of the reflections are deviated from a desired phase in some cases.

### DISCLOSURE OF THE INVENTION

The present invention has been made in view of the above-mentioned circumstances, and an object thereof is to provide an organic EL display apparatus which can use a function of a polarizing plate effectively, and particularly, can suppress lowering of an anti-reflection effect for light entering from the outside in an oblique direction with respect to a display surface.

In order to solve the problems described above, the present invention provides an organic electroluminescence display apparatus of an active matrix system, including:

a substrate;

a polarizing plate disposed on a display surface side being an opposite side of the substrate;

a thin film transistor; and

a planarization layer for reducing an irregular form corresponding to a circuit pattern of the thin film transistor, the planarization layer including on a surface thereof a pixel electrode and an organic electroluminescence device, in which:

the planarization layer includes at least two layers;

a thickness of each of the planarization layers is set to be smaller than a maximum height of irregularities resulting from the thin film transistor;

each of the planarization layers includes a contact hole provided at a distinct planar position and a connection wiring layer capable of electrically connecting the thin film transistor and the pixel electrode via the contact hole; and

the planarization layer provided at a location closest to the organic electroluminescence device includes on the surface thereof a tapered portion having a taper angle set to 30 degrees or less.

According to the organic EL display apparatus of the present invention, a function of the polarizing plate is used effectively to enable light entering from the outside to be suitably reflected and cut, thereby enhancing contrast. In particular, an anti-reflection effect for light entering from the outside in an oblique direction with respect to a display surface is enhanced, which can improve the contrast.

Further features of the present invention will become apparent from the following description of exemplary embodiments with reference to the attached drawings.

### BRIEF DESCRIPTION OF THE DRAWINGS

FIG. 1 is a schematic longitudinal sectional view illustrating an organic EL display apparatus according to an embodiment of the present invention.

FIG. 2 is a schematic plan view illustrating the organic EL display apparatus according the embodiment of the present invention.

FIG. 3 is a schematic longitudinal sectional view illustrating an organic EL display apparatus according to another embodiment of the present invention.

FIG. 4 is an explanatory graph of a relationship between a taper angle and a relative intensity of reflection of external light.

### BEST MODE FOR CARRYING OUT THE INVENTION

Hereinafter, a description is made of embodiments of an organic EL display apparatus according to the present invention.

The organic EL display apparatus according to the embodiments of the present invention includes a polarizing plate disposed on a display surface side being an opposite side of a substrate. The polarizing plate is a member for preventing light entering from the outside from radiating to the outside again by using the fact that reflection causes a rotation direction of polarized light to invert. In other words, the polarizing plate used for the organic EL display apparatus according to the embodiments of the present invention is a combination of a linear polarizing plate and a ¼ wavelength phase difference plate. Specifically, the polarizing plate is provided to a surface of a sealing member or a protective layer which are described below.

Further, a thin film transistor including a channel layer and a gate electrode is formed on a substrate such as glass. A series of patterning is performed on the thin film transistor and irregularities resulting from those circuit patterns are caused. The irregularities have, for example, a maximum height of about from 500 nm to 1,500 nm.

In general, a suitable thickness of each of layers constituting the organic EL device is 500 nm or less. In the case where a marked irregularity is formed on the surface, breaking of wire or thickness fluctuation occurs. Therefore, in order to reduce the irregularities, a planarization layer is provided. The planarization layer is provided with a contact hole and a connection wiring layer to ensure electrical connection between an electrode layer of the thin film transistor and a first electrode layer (pixel electrode). In order to form the contact hole, a photosensitive resin such as acrylic is applied in a predetermined thickness by spin coating or roll coating, and exposure is performed while shifting a focal point intentionally to perform development. With this, a contact hole having a tapered side wall is formed. In this case, when a taper angle (tilt angle) is larger than 30 degrees, light entering from the outside is diffusely reflected, which remarkably lowers an anti-reflection effect due to the polarizing plate. The inventors of the present invention have found that, in the case where a taper angle is set to 30 degrees or less, diffuse reflection of the light entering from the outside is reduced and contrast can be enhanced. A smaller lower limit value of the taper angle is better from the view point of the anti-reflection which is a main effect. However, an area of the contact hole is made larger, and thus the taper angle of several degrees or more may be better from the view point of dimensional design. Specifically, the taper angle can be 5 degrees or more.

The planarization layer includes at least two layers. For planarization of the irregularities, the thickness of the planarization layer is needed to be substantially equal to or larger than the maximum height of the irregularities. When the planarization layer is formed only by a single layer, the contact hole of the planarization layer which is provided for the electrical connection has a lager thickness. Therefore, the planarization layer includes at least two layers to enable the thickness of each layer included in the planarization layer to be smaller than the maximum height of the irregularities, with the result that the thickness of the contact hole can be also made smaller.

Further, each layer included in the planarization layer is gradually made thinner stepwise toward the organic EL device, and the contact hole of each layer included in the planarization layer is provided at a distinct planar position to reduce the depth of a concave at the uppermost portion. Note that, in the case where the first electrode layer of the organic EL device includes the reflective layer which is provided on the contact hole of a lower layer, the tapered portion of the contact hole does not contribute to the reflection, and therefore there is no problem even when the taper angle is 30 degrees or more. As a matter of course, in all the planarization layers, the taper angel of the contact hole provided in the lower layer may be set to 30 degrees or less. The contact hole is not necessarily covered with the reflective layer.

The connection wiring layer which enables the thin film transistor and the first electrode layer to be electrically connected to each other via the contact hole can be formed by patterning using a photolithography technique. Besides, in the case where a panel size is large and definition is less high, the contact hole and the connection wiring layer are formed in multiple steps by an ink jet printing system or printing, and thereafter heated to adjust the form thereof by reflowing to form the tapered portion.

In a conventional technology, the contact hole is formed in portions other than a light emitting portion of a pixel to omit the planarization. Besides, in the case of forming the contact hole in the light emitting portion of the pixel, the planarization is performed through an operation such as polishing after embedding a resin or metal.

In contrast to the above, in the organic EL display apparatus according to the present invention, as the thickness of the contact hole becomes smaller, the irregular form is caused less. As a result, the contact hole can be directly formed in the light emitting portion of the pixel. Therefore, the light emitting portion can be designed to be larger, and the luminance is improved. A driving power used for obtaining the same luminance can be suppressed at a lower level. In a process of forming the planarization layer, different processes such as embedding a resin or metal and polishing are not repeated but the same process is repeated by using the photolithography technique, whereby the planarization layer can be formed with ease.

For the formation of the planarization layer, similarly to a normal photopatterning process, first, a solution including a photosensitive transparent acrylic resin material is applied onto a substrate by spin coating. After that, a series of processes such as pre-baking, pattern exposure, alkali development, and deionized water cleaning may be performed in the stated order.

Specifically, the solution including the photosensitive transparent acrylic resin is applied through the spin coating to obtain a predetermined thickness. With this, the pixel electrode is planarized and irregularities occurring in conventional layers are reduced.

Subsequently, the substrate is heated at about 100° C. to dry a solvent including the photosensitive transparent acrylic resin (such as ethyl lactate or propylene glycol monomethyl ether acetate). Next, exposure is performed on the photosensitive transparent acrylic resin with a desired pattern, and then a developing process is performed by an alkaline solution (tetramethylammonium hydroxide; hereinafter, referred to as TMAH). With this alkaline solution, the exposed portion is etched and therefore a contact hole passing through the planarization layer can be formed.

In addition, a developer remaining on the substrate surface is cleaned with a deionized water. As described above, the layer of the photosensitive transparent acrylic resin can be formed by spin coating. Accordingly, even when the thickness of the layer is 1 μm or less, an uniform thickness of the layer can be obtained with ease by appropriately selecting a revolution speed of a spin coater and a viscosity of the photosensitive transparent acrylic resin. The tapered portion of the contact hole can have a gently inclined form by appropriately selecting an exposure amount at the time of a pattern exposure, a concentration of the developer, and a developing time.

Multiple organic compound layers which have different functions from the first electrode layer and an organic EL device including a second electrode layer are provided on the surface of the planarization layer. The first electrode layer is electrically connected to the thin film transistor through the contact hole provided in the planarization layer. Further, a device isolation layer defining a light emitting portion of a pixel may be formed by covering a part of the first electrode layer.

Except for a connection terminal portion to the exterior, a sealing member such as glass is bonded to the periphery of the substrate to be sealed. In this case, an absorbent material may be disposed on a location other than a light radiating portion within a sealed space, or may be disposed on a location including the light radiating portion when the absorbent material is transparent. Further, a protective layer made of SiON or SiN may be formed in multi-layered manner, or both of the protective layer and the sealing member may be formed.

The polarizing plate is provided on the surface of the sealing member thus formed, with the result that the organic EL display apparatus according to the present invention is completed. The polarizing plate may be bonded to a part of the surface of the sealing member, or to the entire surface thereof. Further, the polarizing plate may be provided to the surface of the sealing member by use of a mechanical fixing method.

Next, with reference to the drawings, a detailed description is made of the organic EL display apparatus according to the present invention.

### Embodiment 1

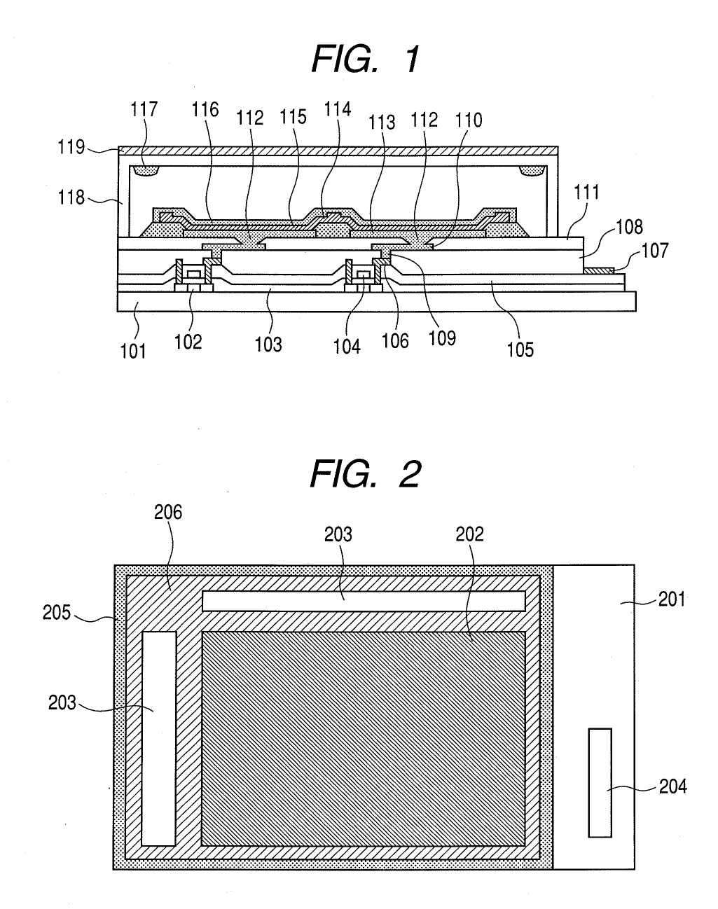

FIGS. 1 and 2 illustrate the organic EL display apparatus according to Embodiment 1 of the present invention. FIG. 1 is a schematic longitudinal sectional view of the organic EL display apparatus, and FIG. 2 is a schematic plan view thereof.

In FIG. 1, a display area is enlarged to be illustrated for two sub-pixels, but actually, for example, the display area has a diagonal size of about 2.5 inches and 320×240 pixels. Each pixel pitch is about 159 μm×53 μm with three sub-pixels each having distinct color per pixel. Further, in the case of a diagonal size of about 15 inches and 1,024×768 pixels, each pixel pitch is about 300 μm×100 μm with three sub-pixels each having distinct color per pixel. A drive circuit is represented by one thin film transistor, but may be formed by multiple transistors, capacitors, and connection wiring layers actually. A control circuit outside the display area is not illustrated in the figure. Note that the present invention can be applied to any display apparatus irrespective of a size or resolution of the display apparatus.

As illustrated in FIG. 2, the drive circuit is provided to a display area 202 according to pixels, and a control circuit 203 is provided outside the display area 202. Components other than a connection terminal 204 are sealed by a sealing member 205. FIG. 2 also illustrates a substrate 201 and a sealed space 206.

In the organic EL display apparatus according to the embodiment of the present invention, a thin film transistor for driving is provided to a corresponding position of each pixel or each sub-pixel on the substrate. Specifically, as illustrated in FIG. 1, first, a barrier layer (not shown) made of SiO₂, SiN, or SiON is formed in a thickness ranging from 100 nm to 200 nm by performing a plasma CVD method on the substrate 101 made of glass, quartz, or silicon. Subsequently, amorphous silicon or microcrystalline silicon is provided in a thickness ranging from 30 nm to 150 nm by the plasma CVD method to form a channel layer 102. The channel layer 102 is polycrystallized by laser annealing to be patterned in a desired form by a photolithography technique.

Next, a gate insulating layer 103 made of SiO₂, SiN, or SiON is formed in a thickness ranging from 50 nm to 200 nm, and a gate electrode 104 made of Ta or W is formed on the gate insulating layer 103 in a thickness ranging from 50 nm to 200 nm by sputtering to be pattered. Note that the gate electrode may be provided under the channel layer 102.

Subsequently, a source region and a drain region of the channel layer 102 are separately doped with phosphorus or boron and then activated by laser beam. On the channel layer 102, a protective layer 105 made of SiO₂, SiN, or SiON is formed in a thickness ranging from 500 nm to 1,000 nm. The photolithography technique is used for the protective layer 105 to pattern an opening for connection, and an electrode layer 106 made of Ti or Al is formed to provide a source electrode and a drain electrode. In this case, the electrode layer 106 can have a thickness ranging from 100 nm to 500 nm and the multi-layered structure.

Each pixel may include multiple thin film transistors. Besides, a capacitor, wiring for the control circuit, and the connection terminal to the exterior may be formed by using the channel layer 102 and the electrode layer 106. Further, a peripheral circuit such as a shift resister for control can also be formed at the same time in the periphery of the display area of the same substrate 101. The example described above is a polycrystalline thin film transistor. However, an amorphous thin film transistor, microcrystalline thin film transistor, a transparent oxide semiconductor such as InGaZnO also cause similar irregularities. Through a series of processes, irregularities resulting from those circuit patterns are caused on the thin film transistor, for example, in the maximum height ranging from about 500 nm to about 1,500 nm.

A first planarization layer 108 for reducing the irregularities is provided on the thin film transistor. In order to form the first planarization layer 108, a photosensitive polyimide resin or a photosensitive acrylic resin is applied by spin coating or roll coating. Next, exposure and development are performed for post-baking. With the processes described above, a contact hole 109 can be formed in a predetermined position. Spin-on-glass (SOG) can be patterned by using a photoresist.

After that, a layer made of aluminum, chromium, silver, magnesium, tin oxide, zinc oxide, indium oxide, or ITO is formed by sputtering. Then, by using the photolithography technique, a connection wiring layer 110 is formed on the first planarization layer 108 via the contact hole 109 so that the connection wiring layer 110 is connected to the electrode layer 106 of the thin film transistor.

Further, a second planarization layer 111 is formed on the connection wiring layer 110. In this process, controlling the viscosity and the revolution speed for spin coating can make the second planarization layer 111 thinner than the first planarization layer 108. Then, a focal length is shifted intentionally to perform exposure on the connection wiring layer 110 and development is performed for post-baking. Through the processes described above, there can be formed a contact hole 112 having a taper angle of 30 degrees or less, through which the connection wiring layer 110 is exposed from the bottom surface of the contact hole 112. Alternatively, two-step exposure is performed by moving a mask to form a tapered portion. The contact hole 112 of the second planarization layer 111 may be provided in a plane position different from the contact hole 109 of the first planarization layer 108. In the case where the panel size is large and definition is less high, patterning is performed by an ink jet printing system or printing to form the tapered portion by reflowing.

A first electrode layer 113 can include tin oxide, zinc oxide, indium oxide, ITO, or IZO. The first electrode layer 113 can also be formed of a mixture or by a stacked structure. For the connection with the thin film transistor, only the first electrode layer 113 may be sufficient, but another conductive layer may be provided for connection. Further, the first electrode layer 113 may be stacked together with the reflective layer of aluminum or silver. In this process, the first electrode layer 113 can be patterned in a form corresponding to the pixel by the photolithography technique.

A layer made of amorphous silicon, SiN, polyimide, or acrylic is formed and patterned. With this, ends of the first electrode layer 113 may be covered and a device isolation layer 114 for limiting a light emitting region may be formed.

Following a sufficient dehydration process such as heating in a vacuum, an organic compound layer 115 is deposited on each corresponding display pixel by a vacuum vapor deposition method using a metal mask. In this process, when an emission light color is different for each display pixel, different materials may be separately deposited more than once. When an emission light color is monochromatic, an electron transport layer or an electron injection layer may be uniformly provided straddling pixels.

The organic compound layer 115 includes an electron transport layer, an emission layer, and a hole transport layer (not shown). The structure of the organic compound layer 115 is not limited thereto. The organic compound layer 115 may be formed in a two-layered structure by using a transport layer serving also as an emission layer, or may be formed in a four-layered or five-layered structure by providing a hole injection layer and electron injection layer.

As a hole transportable substance, for example, triphenyl amines may be used. As the triphenyl amine, N,N′-diphenyl-N,N′-di(3-methylphenyl)-1,1′-diphenyl-4,4′-diamine (TPD) may be used. In addition, N,N′-diphenyl-N,N′-dinaphthyl-1,1′-diphenyl-4,4′-diamine (NPD) may be used as another triphenyl amine. In addition, heterocyclic compounds typified by N-isopropyl carbazole, biscarbazole derivatives, pyrazoline derivatives, stilbene-based compounds, hydrazone-based compounds, oxadiazole derivatives, and phthalocyanine derivatives may be used. In addition, as polymer systems, polycarbonate and polystyrene derivatives having a monomer at their side chain, polyvinyl carbazole, polysilane, polyphenylene vinylene, and the like are preferably used.

As a material for the emission layer, anthracene, pyrene, and 8-hydroquinoline aluminum may be used. In addition, bisstyryl anthracene derivatives, tetraphenyl butadiene derivatives, coumarin derivatives, oxadiazole derivatives, distyrylbenzene derivatives, and pyrrolopyridine derivatives may be used. In addition, perinone derivatives, cyclopentadiene derivatives, and thiadiazopyridine derivatives may be used. In addition, as polymer systems, polyphenylene vinylene derivatives, polyparaphenylene derivatives, polythiophene derivatives, and the like may be used. In addition, as a dopant to be added in the emission layer, rubrene, quinacridone derivatives, phenoxazone 660, DCMl, perinone, perylene, coumarin 540, diazaindacene derivatives, and the like may be used.

As a electron transportable substance, oxadiazole-based derivatives may be used. As the oxadiazole-based derivatives, for example, there are given 8-hydroquinoline aluminum, hydroxybenzoquinoline beryllium, and 2-(4-biphenyl)-5-(4-t-butylphenyl)-1,3,4-oxadiazole (tBuPBD). In addition, oxadiazole dimer-based derivatives such as 1,3-bis(4-t-butylphenyl-1,3,4-oxadizolyl)biphenylene (OXD-1), 1,3-bis(4-t-butylphenyl-1,3,4-oxadizolyl)phenylene (OXD-7), and the like may be used. In addition, triazole-based derivatives, and phenanthroline-based derivatives may be used.

The material used in the hole transport layer, the emission layer, or the electron transport layer can form each layer independently, but may be used by being dispersed in a polymer binder agent. As the polymer binder agent, solvent-soluble resins may be used. For example, polyvinyl chloride, polycarbonate, polystyrene, poly(N-vinylcarbazole), polymethyl methacrylate, polybutyl methacrylate, polyester, polysulfone, polyphenylene ether, and polybutadiene may be used. Further, as the solvent-soluble resin, solvent-soluble resins such as hydrocarbonate resins, ketone resins, phenoxy resins, and polyurethane resins may be used. In addition, curable resins such as phenol resins, xylene resins, petroleum resins, urea resins, melamine resins, unsaturated polyester resins, alkyd resins, epoxy resins, and silicone resins may be used.

A second electrode layer 116 is formed on the organic compound layer 115 uniformly. The second electrode layer 116 can be formed of a transparent conductive material made of tin oxide, zinc oxide, indium oxide, ITO, or IZO. In addition, the electrode layer 106 of the thin film transistor and wiring for extraction which is formed at the same time are connected to each other in the outside of the display area to be connected to the connection terminal.

After that, in order to block oxygen or water penetrating from the outside, a sealing member 118 made of glass and provided with a depression is bonded. In addition, an absorbent material 117 can be disposed in a void space defined by the sealing member 118.

A polarizing plate 119 for display which is commercially available is attached to the surface of the sealing member 118 thus formed to complete the organic EL display apparatus according to the present invention. The polarizing plate 119 may be bonded to a part of the surface of the sealing member 118 or may be bonded to the entire surface of the sealing member 118. Alternatively, the polarizing plate 119 may be attached to the surface of the sealing member 118 by a mechanical fixing method using a spring.

As described above, the organic EL display apparatus having the above structure can suppress the diffuse reflection of the light entering from the outside, the diffuse reflection being generated in the tapered portion of the planarization layer. Therefore, the function of the polarizing plate can be used effectively. In other words, the anti-reflection effect due to the polarizing plate can be enhanced.

In particular, as in Examples described below, the anti-reflection effect for the light entering from the outside in an oblique direction with respect to the display surface is enhanced, which can improve the contrast.

### Embodiment 2

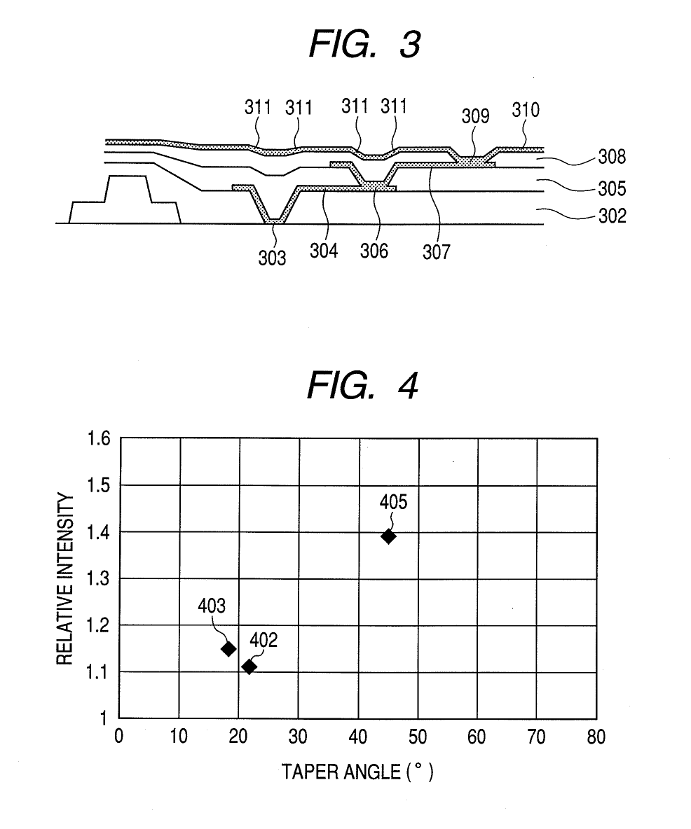

FIG. 3 is a schematic longitudinal sectional view illustrating an organic EL display apparatus according to Embodiment 2 of the present invention.

As illustrated in FIG. 3, three planarization layers 302, 305, and 308 can be provided, a thickness of each of the planarization layers 302, 305, and 308 can be made smaller than the maximum height of the irregularities resulting from the thin film transistor, and further, each of the planarization layers can be gradually made thinner stepwise towards the organic EL device.

In this case, a connection wiring layer 307 formed on the second planarization layer 305 may serve also as the first electrode layer of the organic EL device.

As described above, the organic EL display apparatus having the above structure also can suppress the diffuse reflection of the light entering from the outside, the diffuse reflection being generated in the tapered portion of the planarization layer. Therefore, the function of the polarizing plate can be used effectively. In other words, the anti-reflection effect due to the polarizing plate can be enhanced.

In particular, as in Examples described below, the anti-reflection effect for the light entering from the outside in an oblique direction with respect to the display surface is enhanced, which can improve the contrast.

Hereinafter, the organic EL display apparatus according to the present invention is described with reference to specific examples.

### Example 1

As Example 1, the organic EL display apparatus illustrated in FIGS. 1 and 2 was manufactured. Specifically, in Example 1, a glass substrate of 70 mm per side was used to form the organic EL display apparatus having a diagonal size of about 2.5 inches and 320×240 pixels. Each pixel pitch was 159 μm×53 μm with three sub-pixels each having distinct color.

Specifically, a barrier layer (not shown) was formed on the glass substrate 101 by using the plasma

CVD method. As the barrier layer, a SiN layer was formed in a thickness of 200 nm by using SiH₄, NH₃, and H₂ as source gas. Next, amorphous silicon was provided in a thickness of 50 nm by the plasma CVD method to form the channel layer 102. The channel layer 102 was polycrystallized by laser annealing and patterning was performed thereon by the photolithography technique. In this manner, the channel layer 102 of each of transistors for drive circuit, switching circuit, and control circuit was formed.

Then, the gate insulating layer 103 made of SiO₂ was formed in a thickness of 100 nm. On the gate insulating layer 103, a Ta layer was formed in a thickness of 50 nm, an Al layer was formed in a thickness of 200 nm by sputtering, and patterning was performed to form the gate electrode 104.

The channel layer 102 except for an n-region thereof was protected with a resist and then phosphorus was doped. Then, the channel layer 102 except for a p-region thereof was protected with a resist and then boron was doped. After that, activation by laser beam was performed. The protective layer 105 made of SiN was provided in a thickness of 500 nm on the channel layer 102. An opening for connection was patterned on the protective layer 105 by the photolithography technique, and the electrode layer 106 was formed, which had the two-layered structure of a Ti layer of 100 nm and a TiAl layer of 300 nm. Patterning was further performed to provide the source electrode, the drain electrode, a capacitor electrode, and the connection terminal 107. As a result, an opening for connection of the gate insulating layer 103 and the protective layer 105 made a concave portion of about 600 nm. Aside from this, a convex portion of about 650 nm was made in an overlapping portion of the source electrode, the drain electrode, and the gate electrode. Accordingly, in Example 1, the maximum height of the irregularities resulting from the thin film transistor was 650 nm.

Then, the first planarization layer 108 was provided in order to reduce the irregularities generated on the thin film transistor. Specifically, a polyimide resin (DL1400: manufactured by Toray Industries) was diluted with y-butyrolactone to set the viscosity to 10 mPa·s. The polyimide resin was applied by spin coating at 1,200 rpm. After pre-baking, a photomask having a pattern of the contact hole 109 serving as an opening portion for connection was used for exposure at illumination of 1,800 mW. The polyimide resin was developed with a developer (DV-605: manufactured by Toray Industries) and subjected to post-baking at 200° C. to form the first planarization layer 108. The thickness of the first planarization layer 108 was 800 nm. Then, an ITO layer was formed by sputtering and the connection wiring layer 110 was formed on the first planarization layer 108 by the photolithography technique.

The second planarization layer 111 was formed on the first planarization layer 108. Specifically, a polyimide resin was adjusted to have a viscosity of 6 mPa·s and applied by spin coating at 1,200 rpm. A focal length was shifted intentionally to perform exposure at a position of 15 μm in a direction where the photomask was separated, and the polyimide resin was subjected to development and post-baking. Through the processes described above, the contact hole 112 having a taper angle of 22 degrees was formed. The thickness of the second planarization layer 111 was 300 nm.

The first electrode layer 113 was formed by stacking and patterning an aluminum layer and an ITO layer. An SiN layer was formed and patterned to cover the ends of the first electrode layer 113, and the device isolation layer 114 for limiting a light emitting region was formed.

After that, in a vacuum apparatus, the substrate 101 thus formed was heated at 150° C. under a pressure of 10⁻² Pa for 30 minutes, and the organic compound layer 115 was deposited with a mask under a pressure of 10⁻⁴ Pa. Specifically, as the hole transport layer, α-NPD (N′-α-dinaphthylbenzidine) was formed uniformly in a thickness of 70 nm. As the emission layer corresponding to a red sub-pixel, by using a mask aligning mechanism, CBP(4,4′-N,N′-dicarbazole-biphenyl)+Ir(piq)₃ was formed uniformly in a thickness of 40 nm. Subsequently, the mask position was shifted and Alq3(tris-[8-hydroxyquinolinate]aluminum)+coumarin 6 was formed uniformly in a thickness of 30 nm as the emission layer corresponding to a green sub-pixel. The mask position was further shifted and BAlq was formed uniformly in a thickness of 30 nm as the emission layer corresponding to a blue sub-pixel. Then, as the electron transport layer, Bphen (Bathophenanthroline) was formed uniformly in a thickness of 10 nm. Further, as the electron injection layer, Bphen+C_{S2}CO₃ was formed uniformly in a thickness of 40 nm.

The ITO was used to form the second electrode layer 116 as a cathode entirely by sputtering in a thickness of 60 nm.

After that, the substrate 101 thus formed was transferred within a glove box which is controlled at a dew point of −70° C. or lower, and was bonded with the sealing member 118 made of glass and provided with a depression for blocking oxygen or water penetrating from the outside. In the space defined by the sealing member 118, the absorbent material 117, which was obtained by sticking zeolite with siloxane, was disposed. The polarizing plate 119 for display which was commercially available (Sumikalight (registered trademark): manufactured by Sumitomo Chemical Co., Ltd.) was bonded to the surface of the sealing member 118 with an ultraviolet curing agent to complete the organic EL display apparatus according to Example 1.

Regarding the organic EL display apparatus according to Example 1 thus manufactured, white light was inclined by each inclination of 5 degrees from the position perpendicular to the display surface up to the inclination of 70 degrees, and the reflected light at respective angles of the inclination points was determined by an integrating-sphere photometer and a photo sensor. Then, relative reflection intensities of the respective angles were combined. The determined result was 1.12 as indicated by reference numeral 402 of FIG. 4. FIG. 4 also indicates the results of another example and a comparative example. As is apparent from FIG. 4, in the case where the taper angle of the contact hole is 30 degrees or less, the anti-reflection effect is remarkably exerted.

### Comparative Example 1

As Comparative Example 1, the same organic EL display apparatus as that of Example 1 was manufactured, except for the provision of a gap of 5 μm and the exposure for the second planarization layer 111. The taper angle of the contact hole 112 was about 45 degrees. For Comparative Example 1, the same determination as in Example 1 was made, and it was found that the relative intensity in reflectance was 1.39 as indicated by reference numeral 405 of FIG. 4.

### Example 2

As Example 2, the organic EL display apparatus illustrated in FIG. 3 was manufactured.

In Example 2, the organic EL display apparatus was manufactured by the same processes as those of Example 1 up to the process of manufacturing the thin film transistor. The first planarization layer 302 for reducing the irregularities was formed on the thin film transistor. Specifically, an acrylic resin (PC415: manufactured by JSR Corporation) was diluted with diethylene glycol methyl ethyl ether, and the viscosity was set to 8 mPa·s. Then, the acrylic resin was applied by spin coating at 1,000 rpm. After pre-baking, a photomask having a pattern of the contact hole 303 serving as an opening portion for connection was used for exposure at illumination of 1,800 mW. The acrylic resin was developed with a developer (NMD-3: manufactured by Tokyo Ohka Kogyo Co., Ltd.) and subjected to post-baking at 200° C. to form the first planarization layer 302. The thickness of the first planarization layer 302 was 500 nm in a planarized portion. An ITO layer was formed by sputtering to form a connection wiring layer 304 on the first planarization layer 302 by the photolithography technique.

The second planarization layer 305 was formed on the first planarization layer 302. Specifically, the acrylic resin having the same viscosity as that of the first planarization layer 302 was applied by spin coating at 1,200 rpm. After pre-baking was performed, a photomask having a pattern of a contact hole 306 serving as an opening portion for connection was used for exposure at illumination of 1,800 mW. The acrylic resin was developed with the developer and subjected to post-baking at 200° C. to form the second planarization layer 305. The thickness of the second planarization layer 305 was 400 nm in a planarized portion. An ITO layer was formed by sputtering to form the connection wiring layer 307 on the second planarization layer 305 by the photolithograpy technique.

The third planarization layer 308 was formed on the second planarization layer 305. Specifically, the acrylic resin having the same viscosity as that of the first planarization layer 302 was applied by spin coating at 1,400 rpm. A focal length was shifted intentionally to perform exposure at a position of 20 μm in a direction where the photomask was separated, and the acrylic resin was subjected to development and post-baking. Through the processes described above, a contact hole 309 having a taper angle of about 18 degrees was formed. The thickness of the third planarization layer 308 was 300 nm in a planarized portion. The contact hole 303 of the first planarization layer 302 and the contact hole 306 of the second planarization layer 305 were tapered portions having smaller taper angles than the taper angle of a tapered portion 311 of the contact hole 309 of the third planarization layer 308.

A connection wiring layer 310 formed on the third planarization layer 308 served as the first electrode layer. As described above, the organic EL display apparatus of Example 2 was completed in the same manner as in Example 1. For Example 2, the same determination as in Example 1 was made, and it was found that the relative intensity in reflectance was 1.15 as indicated by reference numeral 403 of FIG. 4.

This application claims the benefit of Japanese Patent Application No. 2007-223649, filed Aug. 30, 2007, which is hereby incorporated by reference herein in its entirety.

1. An organic electroluminescence display apparatus of an active matrix system, comprising:
a substrate;
a polarizing plate disposed on a display surface side being an opposite side of the substrate;
a thin film transistor; and
a planarization layer for reducing an irregular form corresponding to a circuit pattern of the thin film transistor, the planarization layer including on a surface thereof a pixel electrode and an organic electroluminescence device, wherein:
the planarization layer comprises at least two layers;
a thickness of each of the planarization layers is set to be smaller than a maximum height of irregularities resulting from the thin film transistor;
each of the planarization layers comprises a contact hole provided at a distinct planar position and a connection wiring layer capable of electrically connecting the thin film transistor and the pixel electrode via the contact hole; and
the planarization layer provided at a location closest to the organic electroluminescence device comprises on the surface thereof a tapered portion having a taper angle set to 30 degrees or less.

2. The organic electroluminescence display apparatus according to claim 1, wherein the thickness of each of the planarization layers is set to be gradually made smaller stepwise toward the organic electroluminescence device.

3. The organic electroluminescence display apparatus according to claim 1, wherein the contact hole of the planarization layer provided at the location closest to the organic electroluminescence device is provided in a light emitting portion of a pixel.
